(19) United States
(12) Patent Application Publication
(10) Pub. No.: US 2013/0029272 A1
(43) Pub. Date: Jan. 31, 2013

(54) PROCESS FOR PRODUCING FINE PATTERN

(71) Applicant: Hiroe Ishikura, Kawasaki-shi (JP)

(72) Inventor: Hiroe Ishikura, Kawasaki-shi (JP)

(73) Assignee: CANON KABUSHIKI KAISHA, Tokyo (JP)

(21) Appl. No.: 13/639,077

(22) PCT Filed: May 20, 2011
(86) PCT No.: PCT/JP2011/062156

§ 371 Date: Oct. 2, 2012

(30) Foreign Application Priority Data
May 31, 2010 (JP) 2010-125031

(51) Int. Cl. G03F 7/20

(52) U.S. Cl. 430/320; 430/322

(57) ABSTRACT

The present invention provides a process for producing a fine pattern including, (1) forming a first resin layer containing a photosensitive resin on a substrate; (2) forming a second resin layer containing a secondary or tertiary alkynyl alcohol, a photoacid generator, and a resin on the first resin layer; (3) subjecting the second resin layer to pattern exposure; (4)subjecting the first resin layer to exposure using the pattern-exposed portion of the second resin layer as a mask; and (5) removing the second resin layer and the first resin layer.

### TECHNICAL FIELD

The present invention relates to a process for producing a fine pattern using a photosensitive resin.

### BACKGROUND ART

With recent advances in science forming and technology, there has been an increasing need for forming technology for a fine structure in various fields. Extensive research has been conducted in the field of microactuators, electronic devices, optical devices and so on. Such research has advanced, for example, in various miniature sensors, microprobes, thin magnetic heads, and ink-jet heads. Processes for producing such fine structures include stamping, dry etching, and photolithography. Among these, a process for forming a pattern by photolithography using a photosensitive resin can readily form a good shape having a high aspect ratio with high precision.

Japanese Patent Publication No. H06-45242 (Patent Literature 1) discloses a process for producing an ink-jet head having a fine pattern by photolithography. According to this process, an ink-jet head is produced by a method including the following steps. First, an ink flow path pattern is formed of a dissolvable resin on a substrate provided with an energy generation element. Then, a coating resin layer containing an epoxy resin and a cationic photopolymerization initiator is formed on the ink flow path to make ink flow walls, and an ejection orifice is formed on the energy generating element by photolithography. Subsequently, the dissolvable resin is eluted, and the coating resin for making ink flow path walls is cured. In this method, the material used for the ink flow path pattern and the material used for the coating resin layer needs to have different photosensitive wavelength ranges. For example, a positive photosensitive resin containing isopropenyl ketone having sensitivity in the vicinity of 300 nm is used for the ink flow path pattern, while a negative photosensitive resin having sensitivity in the range of not shorter than 300 nm is used for the coating resin layer. Examples of the negative photosensitive resin having sensitivity in the range of not shorter than 300 nm include a cationic polymerizable epoxy resin containing a cationic photopolymerization initiator SP-172 (trade name) available from ADEKA Corporation.

However, a so-called stepper that performs irradiation of single wave-length light using a reduced projection optical system is not used as an exposure apparatus for subjecting the photosensitive resin used for the ink flow path pattern to exposure. Instead, such an exposure apparatus as to subject the entire substrate to exposure with 1:1 magnifying power at the same time is used. In the case of subjecting the photosensitive resin to exposure with such an exposure apparatus as to perform irradiation of deep UV light corresponding to each of the photosensitive wavelength ranges for the photosensitive resins at the same time, the following problems may arise.

A first problem is that alignment accuracy between the substrate and a mask may be insufficient due to the apparatus configuration that subjects the large area to exposure at the same time. In particular, when a large wafer having a size of 8 inch to 12 inch is subjected to exposure, the alignment accuracy may widely vary in a substrate or between substrates due to warpage of the substrate or flexure of the mask.

A second problem is that the main chain cleavable positive photosensitive resin described above needs to be irradiated with a large amount of energy for causing sufficient cleavage reaction because the resin inherently has low sensitivity. Due to the evolution of heat during the exposure, the resulting nonuniform thermal expansion in the mask and the substrate may cause insufficient resolution and alignment accuracy.

In the step of exposure described above, the photosensitive resin for the ink flow path pattern or the flow path walls is usually subjected to exposure with reference to an alignment mark formed on the substrate. Due to the problems described above, however, the positional relation between the energy generating element or the ejection orifice and the ink flow path pattern may be different from the intended relation in some instances. In addition, the resulting disturbance such as dot misalignment in the ink ejecting direction or massive generation of satellites may cause defective performance in printing in some instances.

In order to improve the resolution and alignment accuracy of the pattern made by photolithography described above, a portable conformable mask (PCM) process using two-layer photosensitive resins is known. In the PCM process, the lower layer is formed with a photosensitive resin, and the upper layer is formed with a material that blocks the photosensitive wavelength range of the lower layer. Patterning is then performed by subjecting the upper layer to exposure and developing the layer to make a mask. Then, the lower layer of the photosensitive resin is patterned using this mask. This process is widely used for producing a pattern with a high resolution and a high accuracy as in Japanese Patent Publication No. S63-58367 (Patent Literature 2).

### CITATION LIST

### Patent Literature

PTL 1: Japanese Patent Publication No. H06-45242

PTL 2: Japanese Patent Publication No. S63-58367

According to the process described in Patent Literature 2, however, manufacturing loads are high in some cases due to many process steps, since the mask is formed after the upper layer is subjected to exposure and developed. In addition, materials need to be selected so that the developing fluid during patterning of the upper layer does not dissolve the lower layer.

Accordingly, an object of the present invention is to provide a process for producing a fine pattern having high accuracy and high alignment accuracy with fewer process steps.

### SUMMARY OF INVENTION

The present invention provides a process for producing a fine pattern, including:

(1) forming a first resin layer containing a photosensitive resin on a substrate;

(2) forming a second resin layer containing a secondary or tertiary alkynyl alcohol, a photoacid generator, and a resin on the first resin layer;

(3) subjecting the second resin layer to pattern exposure;

(4) subjecting the first resin layer to exposure using the pattern-exposed portion of the second resin layer as a mask; and

(5) removing the second resin layer and the first resin layer.

According to the present invention, a fine pattern having high accuracy and high alignment accuracy can be formed with fewer process steps. Furthermore, selectivity of the material used for the fine pattern is enhanced.

Further features of the present invention will become apparent from the following description of exemplary embodiments with reference to the attached drawings.

### BRIEF DESCRIPTION OF DRAWINGS

FIG. 1A to FIG. 1E are cross-sectional views illustrating steps of producing a fine pattern in an embodiment of the present invention.

FIG. 2A to FIG. 2K are cross-sectional views illustrating steps of producing a liquid ejection head.

FIG. 3 is a schematic perspective view illustrating a configuration example of a liquid ejection head.

FIG. 4 is a graph showing changes in absorbance due to rearrangement reaction of 1,1,3-triphenylpropargyl alcohol as a typical example of secondary or tertiary alkynyl alcohols.

### DESCRIPTION OF EMBODIMENTS

The present invention will further be described in detail below.

### Embodiment 1: A Process for Producing a Fine Pattern

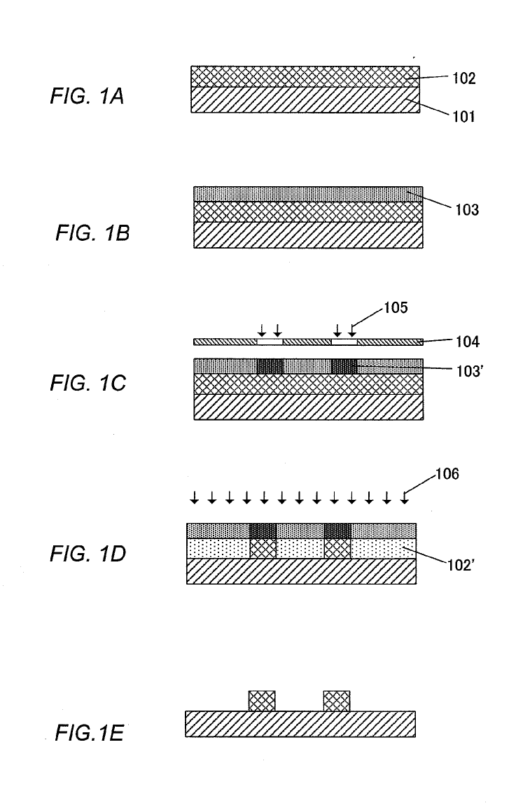

First, a substrate 101 is prepared as illustrated in FIG. 1A.

Any substrate that functions as a base of a fine structure to be formed can be used and are not specifically limited according to the shape or material. For example, a silicon wafer can be used.

Secondly, a first resin layer 102 containing a photosensitive resin is formed on the substrate 101.

Although the photosensitive resin used for the first resin layer is not specifically limited so far as the resin has photosensitivity and enables patterning, preferably a positive photosensitive resin is used. Examples of the positive photosensitive resin include a main chain cleavable photosensitive polymer resin mainly composed of polymethyl isopropenyl ketone or methacrylate ester. Examples of the main chain cleavable positive photosensitive polymer resin include a homopolymer such as polymethyl methacrylate and polyethyl methacrylate or a copolymer of methyl methacrylate and methacrylic acid, acrylic acid, glycidyl methacrylate, or phenyl methacrylate. These main chain cleavable positive photosensitive polymer resins usually have a photosensitive wavelength range around 200 nm to 240 nm. Polymethyl isopropenyl ketone has a photosensitive wavelength range around 260 nm to 320 nm.

Subsequently, a second resin layer 103 containing a secondary or tertiary alkynyl alcohol, a photoacid generator, and a resin is formed on the first resin layer 102, as illustrated in FIG. 1B.

The resin contained in the second resin layer is used for fixing a secondary or tertiary alkynyl alcohol to form a layer. The material for use needs to transmit the wavelength for subjecting the first photosensitive resin layer to exposure.

In the present invention, the first resin layer can be subjected to exposure without developing of the second resin layer for patterning. Preferably the resin contained in the second resin layer does not absorb the light used for subjecting the first resin layer to exposure at all, though slight absorption does not matter. For example, it is preferred that the resin contained in the second resin layer transmit 10% or more of the light in the photosensitive wavelength range of the photosensitive resin used for the first resin layer.

Preferably the second resin layer is subjected to exposure with a stepper from the viewpoint of alignment accuracy. Preferably patterning of the second resin layer can be performed using i-line (365 nm) that is most widely used.

It is known that acid treatment of a secondary or tertiary alkynyl alcohol produces vinyl ketone by the Meyer-Schuster rearrangement reaction.

Preferably a tertiary alkynyl alcohol represented by the following formula is used as a secondary or tertiary alkynyl alcohol.

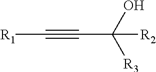

(wherein R₁ represents a hydroxyl group, an alkyl group having 1 to 6 carbons, or an aryl group, R₂ represents a hydrogen atom, an alkyl group having 1 to 6 carbons, or an aryl group, and R₃ represents an aryl group.)

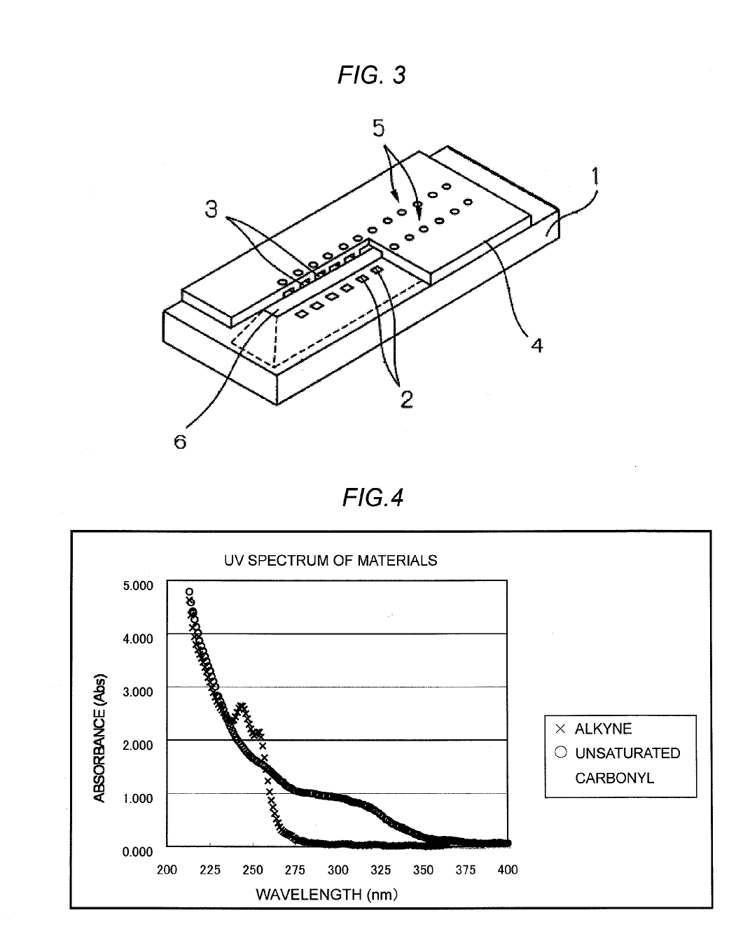

The rearrangement reaction of 1,1,3-triphenylpropargyl alcohol as a typical example of tertiary alkynyl alcohols is represented in Formula 1 below. Changes in absorbance of the material due to the rearrangement reaction are shown in the graph in FIG. 4.

Meyer-Schuster Rearrangement

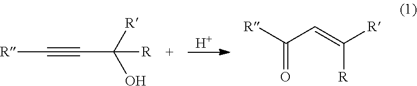

Absorption spectrum of 1,1,3-triphenylpropargyl alcohol which is a tertiary alkynyl alcohol shows absorption of light in a wavelength range of shorter than 260 nm and no absorption or high transmission of light in a wavelength range of not shorter than 280 nm. In contrast, the vinyl ketone that is produced by acid treatment through the Meyer-Schuster rearrangement reaction has less capability of absorption of light in a wavelength range of 230 nm to 260 nm and intensively absorbs light in a wavelength range of 260 nm to 350 nm compared to 1,1,3-triphenylpropargyl alcohol.

As a result, when the second resin layer is subjected to exposure for inducing the Meyer-Schuster rearrangement reaction of a secondary or tertiary alkynyl alcohol, the exposed portion absorbs light in a wavelength range of 260 nm to 350 nm and the unexposed portion transmits light in a wavelength range of not shorter than 280 nm. Accordingly, when the first resin layer and the second resin layer are subjected to exposure with light including light, for example, in a wavelength range of 280 nm to 350 nm, the exposed portion of the second resin layer functions as a mask so that the first resin layer can be subjected to exposure with light that transmits through the unexposed portion.

Since the first resin layer can be subjected to exposure without developing of the second resin layer, a simplified process can be achieved.

(1) A case in which positive polymethyl isopropenyl ketone is used for the first resin layer

First, the second resin layer on the first resin layer is subjected to pattern-exposure 105 (a first exposure) through a reticle 104 (FIG. 1C) to generate acid at the exposed spot. The exposure is performed in a photosensitive wavelength range of a photoacid generator contained in the second resin layer. The photosensitive wavelength of the photoacid generator in the present embodiment may be, for example, 365 nm.

The resin contained in the second resin layer is not specifically limited so far as the resin transmits light in a wavelength range (260 nm to 320 nm) in which photosensing of polymethyl isopropenyl ketone can be caused, and acts as a reaction field of the rearrangement reaction. Preferably the resin contained in the second resin layer is selected with consideration for ease of lamination on the lower layer and post-removal. Examples include a phenol resin and PMMA. The coating solvent of these resins is not specifically limited so far as the solvent enables dissolving the resin. For example, a polar solvent such as methyl isobutyl ketone, 2-heptanone, or propylene glycol monomethyl ether acetate can be favorably used.

Preferably the exposure is performed with a stepper from the viewpoint of alignment accuracy. Preferably the exposure is performed using i-line (365 nm) that is most widely used.

Examples of the photoacid generator include an onium salt, a borate, a triazine compound, an azo compound, and a peroxide. An aromatic sulfonium salt or an aromatic iodonium salt is favorably used from the viewpoints of sensitivity, stability, reactivity, and solubility. Examples of the aromatic sulfonium salt include “TPS-102, 103, and 105”, “MDS-103, 105, 205, and 305”, and “DTS-102 and 103” available from Midori Kagaku Co., Ltd. or “SP-152 and SP-172” available from ADEKA Corporation. Examples of the aromatic iodonium salt include “DPI-105”, “MPI-103 and 105”, “BBI-101, 102, 103, and 105” available from Midori Kagaku Co., Ltd. In the present embodiment, the photoacid generator is not limited thereto, so far as it is photosensitive to light at 365 nm.

In the case of using a photoacid generator with less capability of absorbing light at 365 nm, a sensitizer may be used in combination.

The acid generated by the exposure promotes the Meyer-Schuster rearrangement reaction of the secondary or tertiary alkynyl alcohol to produce vinyl ketone. Preferably a heating process is added in order to enhance the rearrangement reaction. In particular, since the reaction field of the Meyer-Schuster rearrangement reaction is in a resin layer in the present invention, the reaction proceeds weakly compared to that in a conventionally-used liquid reaction field. Accordingly, it is preferred to enhance the reaction yield by heating also to clearly define contrast between reacted and unreacted portions. Meanwhile, since the reaction field of the Meyer-Schuster rearrangement reaction is in a resin layer, a small amount of acid generated during patterning by the overall exposure after forming a latent image mask does not damage the contrast of the latent image mask without a heating process. Also in order to preserve the reactivity in the first resin layer, preferably the heating temperature for effective progress of the rearrangement reaction is not higher than 90° C.

Resulting from the rearrangement reaction, vinyl ketone is present in the exposed portion of the second resin layer and a secondary or tertiary alkynyl alcohol is present in the unexposed portion, and a latent image pattern 103′ with a in-plane difference in absorbance is formed (FIG. 1C).

The first resin layer containing positive polymethyl isopropenyl ketone has a photosensitive wavelength around 260 nm to 320 nm. As a result, when the first resin layer is subjected to exposure 106 (second exposure) through the second resin layer with light of 260 nm to 320 nm, light of not shorter than 280 nm transmits through the portion of the second resin layer containing a secondary or tertiary alkynyl alcohol. Accordingly, polymethyl isopropenyl ketone on the lower side of the portion of the second resin layer containing a secondary or tertiary alkynyl alcohol is subjected to exposure (102′ in FIG. 1D). On the other hand, the portion having the upper layer containing vinyl ketone is not subjected to exposure because light of 230 nm to 350 nm is blocked. Consequently, the latent pattern in the second resin layer functions as a mask, and the pattern can be transferred to the first resin layer.

(2) A case in which an acryl copolymer such as positive methacrylate polymer is used for the first resin layer By the same process as in (1), exposure is performed through a mask and via a proper heating process to form a latent image pattern having a difference in absorbance in the second resin layer. The first resin layer of a positive methacrylate polymer has a photosensitive wavelength around 200 nm to 240 nm. The location having the upper resin layer portion containing a secondary or tertiary alkynyl alcohol generates an unexposed portion due to light blocking. On the other hand, the first resin layer is subjected to exposure where the second resin layer portion contains vinyl ketone, because the absorbance at 230 nm to 260 nm is reduced compared to where the second resin layer portion contains a secondary or tertiary alkynyl alcohol. Consequently, the latent pattern in the second resin layer functions as a mask, and the pattern can be transferred to the first resin layer.

A secondary or tertiary alkynyl alcohol and vinyl ketone produced by the rearrangement reaction scarcely contaminate a production line and do not block the curing reaction by acid to be performed later as needed.

Preferably the amount of a secondary or tertiary alkynyl alcohol added is in the range of 1 wt % to 20 wt % of the solid content of the second resin layer. Also preferably the amount of the photoacid generator added is in the range of 1 wt % to 50 wt % of a secondary or tertiary alkynyl alcohol. The amounts added are not limited thereto so far as capability of light blocking is achieved. Accordingly, it is desirable to adjust the amounts added according to the absorbance of the first resin layer. Although a case in which a positive photosensitive resin is used for the first resin layer is described in the present description, the first resin layer needs not to be of the positive type in the present invention. In other words, patterning of a first resin layer of the negative type can be performed without problems.

Subsequently, using the photosensitive wavelength of the first resin layer an overall exposure is performed through the latent image pattern of the second resin layer, the second resin layer is removed, and the first resin layer is developed to form a pattern.

On this occasion, since the rearrangement reaction proceeds in the second resin layer while a cross-linking reaction does not proceed, removal is performed without difficulty. Furthermore, in the case of using a resin that is dissolvable into the developing fluid of the first resin layer, development is performed in developing the first resin layer at the same time.

Through the process steps described above, a fine pattern with high accuracy of controlled alignment can be formed.

In order to form the first resin layer and the second resin layer, a known application method such as spin coating, roll coating, or slit coating may be used. Alternatively the formation may be performed by laminating dry-film positive photosensitive resins. Furthermore, in order to prevent reflection from the substrate surface, an additive such as light-absorbing agent may be added to the first resin layer.

Embodiment 2: A Process for Producing an Ink-Jet Recording Head

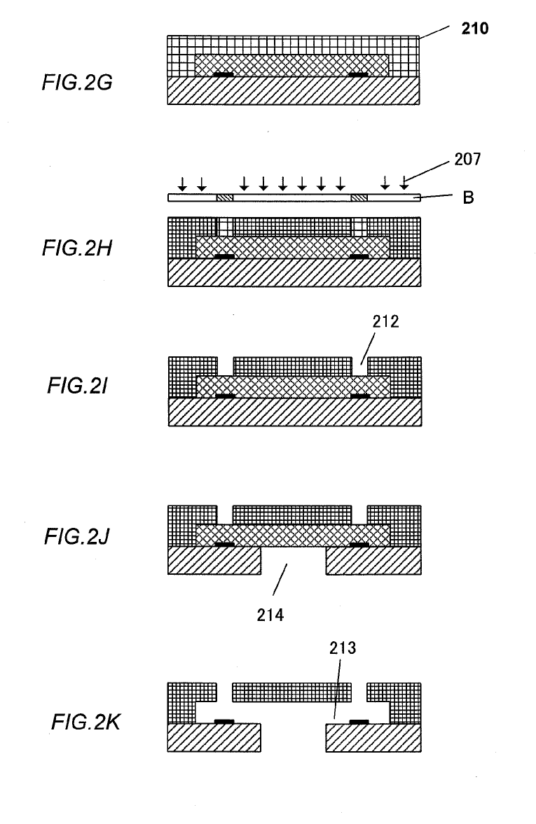

As an embodiment of the present invention, a process for producing a liquid ejection head (FIG. 3) such as an ink-jet recording head is described below. In FIG. 3, a flow path forming member 4 is provided on a substrate 1 formed of silicon or the like. The flow path forming member 4 composes a liquid flow path such as an ejection orifice 5 that ejects a liquid droplet and an ink flow path communicating with the ejection orifice. An ejection energy generating element 2 is provided within the liquid flow path 3 on the substrate 1 so as to eject a liquid droplet with the energy generated by the ejection generating element 2. Also on the substrate 1, a feed opening 6 for feeding liquid such as ink to the liquid flow path 3 is provided.

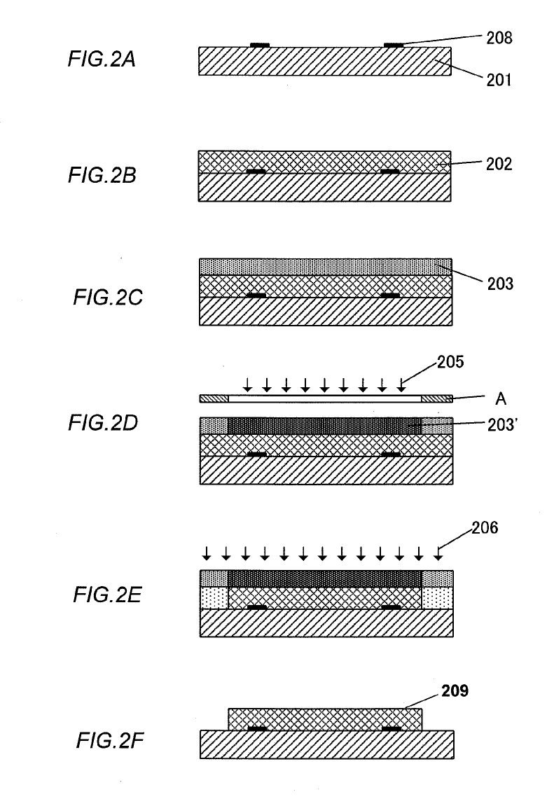

First, a substrate 201 having an energy generating element 208 is prepared as illustrated in FIG. 2A.

The shape or the material of the substrate for use is not specifically limited, so far as the substrate functions as a flow path bottom forming member and as a support of the flow path forming member composing the ink flow path and the ink ejection orifice to be hereinafter described. For example, a silicon substrate may be used as the substrate.

The substrate 201 has the energy generating element 208. For example, an intended number of energy generating elements 208 such as electricity-heat conversion elements or piezoelectric elements may be provided on the substrate 201. Ejection energy for ejecting an ink droplet is given to the ink by driving the energy generating element 208, so as to eject the liquid droplet to a recording medium for recording. For example, in the case of using an electricity-heat conversion element as the energy generating element, the energy generating element heats the adjacent ink so as to change the state of ink, thereby generating ejection energy. For another example, in the case of using a piezoelectric element, mechanical vibration of the energy generating element generates ejection energy.

To the energy generating elements 208, electrodes (not shown in drawings) for receiving control signals for driving the elements are connected. In general, a protective layer (not shown in drawings) can be provided in order to enhance durability of these energy generating elements 208. Also, an adhesion-enhancing layer (not shown in drawings) can be provided on the substrate in order to enhance the adhesion of the flow path forming member to be hereinafter described to the substrate. In the present invention also, such functional layers may be provided without problems.

Subsequently, as a first resin layer, the first resin layer 202 formed of a positive photosensitive resin is provided on the substrate 201 including the energy generating elements 208 as illustrated in FIG. 2B.

For a positive photosensitive resin layer, a main chain cleavable photosensitive polymer resin mainly composed of, for example, polymethyl isopropenyl ketone or methacrylate ester may be used.

Subsequently, a secondary resin layer 203 containing a secondary or tertiary alkynyl alcohol and a photoacid generator is formed on the first resin layer 202 as illustrated in FIGS. 2C and 2D. Then, exposure 205 (first exposure) is performed through a mask A so as to form a patterned latent image 203′.

Subsequently, the first resin layer is subjected to exposure 206 (second exposure) through the mask of patterned latent image 203′ by the same process for producing a fine pattern described in (A) as illustrated in FIG. 2E.

Subsequently, the second resin layer 203 is removed and the first resin layer 202 is developed, to form a flow path pattern to make a mold material of an ink flow path as illustrated in FIG. 2F.

Subsequently, a flow path forming member 210 is formed on a flow path pattern 209 by spin coating, roll coating, or slit coating, as illustrated in FIG. 2G.

Since the flow path forming member functions as a member composing an ink flow path and an ink ejection orifice, high mechanical strength, adhesion to the substrate, durability against ink, and resolution capability for fine patterning of the ink ejection orifice are required. Considering materials to satisfy the required properties, a cationic polymerized epoxy resin compound may be used preferably.

Examples of the epoxy resin include a reaction product of bisphenol A and epichlorohydrin with a molecular weight of not lower than about 900, a reaction product of bromine-containing bisphenol A and epichlorohydrin, and a reaction product of phenol novolac or o-cresol novolac and epichlorohydrin. Although the examples also include a multifunctional epoxy resin having an oxycyclohexane skeleton disclosed in Japanese Patent Laid-Open No. 60-161973, Japanese Patent Laid-Open No. 63-221121, Japanese Patent Laid-Open No. 64-9216, and Japanese Patent Laid-Open No. 02-140219, the epoxy resin is not limited thereto.

Preferably a compound having an epoxy equivalent of not higher than 2000, more preferably a compound having an epoxy equivalent of not higher than 1000, is suitably used as the epoxy resin. The reason is that with an epoxy resin equivalent of not higher than 2000, a proper crosslink density is achieved during curing reaction, and adhesion and durability against ink can be good.

As a photocationic polymerization initiator for curing the epoxy resin, a photoacid generator that generates acid by irradiating light may be used. Although the photoacid generator is not specifically limited, for example, an aromatic sulfonium salt or an aromatic iodonium salt may be used. Examples of the aromatic sulfonium salt include “TPS-102”, “TPS-103”, “TPS-105”, “MDS-103”, “MDS-105”, “MDS-205, “MDS-305”, “DTS-102” and “DTS-103” available from Midori Kagaku Co., Ltd. or “SP-170” and “SP-172” available from ADEKA Corporation. An aromatic iodonium salt such as “DPI-105”, “MPI-103 “MPI-105”, “BBI-101”, “BBI-102”, “BBI-103”, or “BBI-105” available from Midori Kagaku Co., Ltd. is suitably used. The amount added may be adjusted so as to achieve the intended sensitivity. In particular, a preferable range for use is from 0.5 wt % to 5 wt % of the epoxy resin compound. In addition, a wavelength sensitizer may be added as required. Examples of the wavelength sensitizer include “SP-100” available from ADEKA Corporation.

Furthermore, an appropriate amount of additives may be added to the epoxy resin compound as required. For example, a flexibility enhancing agent for reducing the elastic modulus or a silane coupling agent for strengthening adhesion to the substrate may be added.

A layer of an ink-repellent agent having negative photosensitivity may be formed on the flow path forming member 210 as required (not shown in drawings). The ink-repellent agent can be formed by such a coating method as spin coating, roll coating, or slit coating. When the ink-repellent agent is applied on the uncured flow path forming member, it is required that both do not mutually dissolve too much.

Subsequently, for example using an i-line stepper, exposure 207 is performed through a mask B for forming an ejection orifice, as illustrated in FIG. 2H.

Subsequently, an ejection orifice 212 is formed by conducting development as illustrated in FIG. 21.

On this occasion, the ink flow path pattern containing the positive photosensitive resin may be dissolved and removed with the development. In general, a plurality of ink-jet heads are formed on a substrate, and a discrete ink-jet head for use is produced through a cutting process. For dealing with dusts resulting from the cutting process, preferably the ink flow path pattern is left during cutting and then dissolved and removed after the cutting process. Thereby, since the ink flow path pattern remains during cutting, entering into the flow path is prevented.

Subsequently, an ink feed opening 214 penetrating through the substrate 201 including the energy generating element 208 is formed as illustrated in FIG. 2J.

Examples of the process for forming the ink feed opening include sandblasting, dry etching, and wet etching, or a combination of these processes.

As an example, anisotropic etching with an alkali etching liquid such as aqueous solution of potassium hydroxide, sodium hydroxide, or tetramethylammonium hydroxide is described. In an alkaline chemical etching of a silicon substrate having a crystal orientation of <100> or <110>, selection of the depth direction and width direction of the etching propagation is possible. Anisotropy of etching is achieved thereby. In particular, the etching depth of a silicon substrate having a crystal orientation of <100> can be controlled, because the depth is geometrically determined depending on the width to be etched. For example, a hole narrowing from the starting surface of etching toward depth at a tilt angle of 54.7° can be formed.

An ink feed opening penetrating through the substrate can be formed with the anisotropic etching using a mask of an appropriate resin material having durability against the etching solution.

Subsequently, the upper surface of the flow path forming member is irradiated with a photosensitive wavelength of the first positive photosensitive resin layer as required, and the ink flow path pattern is dissolved and removed, to form an ink flow path 213, as illustrated in FIG. 2K.

Subsequently, through a cutting process (not shown in drawings), the flow path forming member is further cured by heating as required. Then, a member for supplying ink (not shown in drawings) is connected, and electrical connection (not shown in drawings) is performed for driving the energy generating element, to make an ink-jet head.

### EXAMPLES

As examples of the present invention, a process for producing an ink-jet head is described below.

### Example 1

### An Ink-Jet Head was Made in Accordance with the Steps Shown in FIGS. 2A to 2K

First, a substrate 201 was prepared as illustrated in FIG. 2A. In the present example, an 8-inch silicon substrate was prepared. A silicon substrate having an electricity-heat conversion element (TaSiN heater) thereon as an energy generating element and a laminated film (not shown in drawings) of SiN (lower layer) and Ta (upper layer) on the ink flow path and the nozzle forming position was prepared.

Subsequently, a positive photosensitive resin as a first resin layer 202 was formed on the substrate 201 as illustrated in FIG. 2B. Specifically, polymethyl isopropenyl ketone was spin coated on the substrate 201 and baked at 120° C. for 6 minutes so as to form the first resin layer 202. After baking, the thickness of the first resin layer was 15 μm.

Subsequently, a second resin layer 203 having the following composition was laminated on the first resin layer 202 so as to have a thickness of 4 μm as illustrated in FIG. 2C.

AV Light EP4050G (trade name, available from Asahi Organic Chemicals Industry Co., Ltd.): 40 parts by mass 1,1,3-triphenylpropargyl alcohol: 2 parts by mass SP-172 (trade name, available from ADEKA Corporation): 0.4 part by mass 2-heptane: 60 parts by mass

Subsequently, using an i-line stepper (available from Canon Inc., trade name: i5), exposure with an exposure amount of 3000 J/m² was performed through a first photomask A, and the Meyer-Schuster rearrangement reaction was allowed to proceed at 90° C. for 3 minutes, as illustrated in FIG. 2D. Due to the Meyer-Schuster rearrangement reaction occurring at the exposed portion due to the exposure, the absorbance of the exposed portion of the second resin layer changed. As a result, a latent image pattern 203′ with a difference in absorbance was formed in the second resin layer 203.

Subsequently, an overall exposure with an exposure amount of 14 J/cm² was performed with the latent image pattern 203′ in the second resin layer as a mask using a deep UV exposure apparatus (available from Ushio Inc., trade name: UX-3000), as illustrated in FIG. 2E.

Subsequently, removal of the second resin layer and development of the first resin were concurrently performed with methyl isobutyl ketone so as to form a flow path pattern 209 as illustrated in FIG. 2F.

Subsequently, a photosensitive resin composition having the following composition was applied onto the flow path pattern 209 and the substrate 201 by spin coating so as to form a film with a thickness of 15 μm followed by prebaking at 90° C. for 2 minutes (hot plate) so as to form a flow path forming member 210, as illustrated in FIG. 2G.

EHPE (available from Daicel Chemical Industries, Ltd.): 100 parts by mass

SP-172 (available from ADEKA Corporation): 5 parts by mass

A-187 (available from Dow Corning Toray Co., Ltd.): 5 parts by mass

Methyl isobutyl ketone: 100 parts by mass

Subsequently, a photosensitive resin composition having the following composition was applied onto the flow path forming member 210 by spin coating so as to form a film with a thickness of 1 μm followed by prebaking at 80° C. for 3 minutes (hot plate) so as to form a liquid-repellent layer (not shown in drawings).

EHPE (available from Daicel Chemical Industries, Ltd.): 35 parts by mass

2,2-bis(4-glycidyloxyphenyl)hexafluoropropane: 25 parts by mass

1,4-bis(2-hydroxyhexafluoroisopropyl)benzene: 25 parts by mass

3-(2-perfluorohexyl)ethoxy-1,2-epoxypropane: 16 parts by mass

A-187 (available from Dow Corning Toray Co., Ltd.): 4 parts by mass

SP-172 (available from ADEKA Corporation): 5 parts by mass Diethylene glycol monoethyl ether: 100 parts by mass

Subsequently, using an i-line stepper (available from Canon

Inc., trade name: i5), pattern exposure with an exposure of 4000 J/m² was performed as illustrated in FIG. 2H. In addition, PEB was performed with a hot plate at 90° C. for 240 seconds.

Subsequently, development with methyl isobutyl ketone, rinsing with isopropyl alcohol, and heat-treatment at 140° C. for 60 minutes were performed for forming an ink ejection orifice 212 as illustrated in FIG. 21. In the present example, an ink ejection orifice with a diameter of 8 μm was formed. Also an ink feed opening 214 was formed as illustrated in FIG. 2J.

Subsequently, an overall exposure with an exposure amount of 250000 J/cm² was performed from the side of the flow path forming member with a deep UV exposure apparatus (available from Ushio Inc., trade name: UX-3000) for solubilization of the ink flow path pattern, as illustrated in FIG. 2K. Through immersion in methyl lactate with ultrasonic agitation, the ink flow path pattern was dissolved and removed, so as to form an ink flow path 213. In the present example, formation of an ink feed opening 214 was omitted.

While the present invention has been described with reference to exemplary embodiments, it is to be understood that the invention is not limited to the disclosed exemplary embodiments.

This application claims the benefit of Japanese Patent Application No. 2010-125031, filed May 31, 2010, which is hereby incorporated by reference herein in its entirety.

1. A process for producing a fine pattern, comprising:
(1) forming a first resin layer containing a photosensitive resin on a substrate;
(2) forming a second resin layer containing a secondary or tertiary alkynyl alcohol, a photoacid generator, and a resin on the first resin layer;
(3) subjecting the second resin layer to pattern exposure;
(4) subjecting the first resin layer to exposure using a pattern-exposed portion of the second resin layer as a mask; and
(5) removing the second resin layer and the first resin layer.

2. The process for producing a fine pattern according to claim 1, wherein the secondary or tertiary alkynyl alcohol is a compound represented by the following formula: 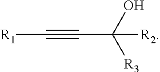
wherein R₁ represents a hydroxyl group, an alkyl group having 1 to 6 carbon atoms, or an aryl group, R₂ represents a hydrogen atom, an alkyl group having 1 to 6 carbon atoms, or an aryl group, and R₃ represents an aryl group.

3. The process for producing a fine pattern according to claim 1, wherein the photoacid generator has photosensitivity to light with a 365 nm wavelength.

4. The process for producing a fine pattern according to claim 1, wherein a resin contained in the second resin layer transmits 10% or more of light in a photosensitive wavelength range of the photosensitive resin.

5. The process for producing a fine pattern according to claim 1, wherein the photosensitive resin is a positive photosensitive resin.

6. The process for producing a fine pattern according to claim 5, wherein the positive photosensitive resin is a main chain cleavable positive photosensitive resin.

7. The process for producing a fine pattern according to claim 6, wherein the positive photosensitive resin is polymethyl isopropenyl ketone or an acryl copolymer.

8. A process for producing a liquid ejection head having a substrate provided with an energy generating element for ejecting liquid and having on the substrate a flow path forming member composing an ejection orifice for ejecting the liquid and a liquid flow path communicating with the ejection orifice, the process comprising forming a flow path pattern to be a mold material of the liquid flow path by the process for producing a fine pattern according to claim 1.
